(19) United States
(12) Patent Application Publication
(10) Pub. No.: US 2018/0051374 A1
(43) Pub. Date: Feb. 22, 2018

(54) FILM-FORMING APPARATUS, FILM-FORMING METHOD, AND STORAGE MEDIUM

(71) Applicant: TOKYO ELECTRON LIMITED, Tokyo (JP)

(72) Inventors: Hitoshi KATO, Oshu-shi (JP); Masahiro MURATA, Oshu-shi (JP)

(21) Appl. No.: 15/671,395

(22) Filed: Aug. 8, 2017

(30) Foreign Application Priority Data
Aug. 17, 2016 (JP) 2016-160147

(51) Int. Cl. C23C 16/455; C23C 16/458

(52) U.S. Cl. CPC C23C 16/45544; C23C 16/4584

(57) ABSTRACT

A film-forming apparatus includes: a rotary table installed inside a vacuum vessel, and including a substrate mounting region, on which the substrate is mounted, formed at one surface side of the rotary table; a heating part for heating the substrate mounted on the rotary table; a first process region in which the source gas is supplied toward the substrate mounting region to perform a first process; a second process region defined apart from the first process region in a circumferential direction of the rotary table via a separation portion, and in which the reactant gas is supplied to perform a second process; and a main nozzle, a central-side auxiliary nozzle and a peripheral-side auxiliary nozzle installed in the first process region to extend in a direction intersecting with a movement path of the rotary table and along a rotational direction of the rotary table.

### CROSS-REFERENCE TO RELATED APPLICATION

This application is based upon and claims the benefit of priority from Japanese Patent Application No. 2016-160147, filed on Aug. 17, 2016, the entire contents of which are incorporated herein by reference.

### TECHNICAL FIELD

The present disclosure relates to a technique for sequentially supplying process gases which react with each other to a substrate so as to laminate reaction products on a surface of the substrate.

### BACKGROUND

As one of techniques for forming a thin film such as a silicon nitride film on a semiconductor wafer (hereinafter, referred to as a “wafer”) which is a substrate, there is known an Atomic Layer Deposition (ALD) method in which a source gas and a reactant gas are sequentially supplied to the surface of the wafer to laminate reaction products. As a film-forming apparatus for performing a film-forming process using such an ALD method, for example, there is a configuration in which a rotary table for rotating a plurality of wafers arranged in the circumferential direction thereof is installed inside a vacuum vessel.

In such a film-forming apparatus, a gas nozzle is installed horizontally so as to extend in the radial direction of the rotary table, and a large number of gas discharge holes are arranged in the lower side of the gas nozzle in a region corresponding to a passage region of the wafer. Then, by discharging the gas downward from the gas discharge holes while rotating the rotary table, each of the source gas and the reactant gas is supplied to the entire surface of the wafer. For example, the source gas such as dichlorosilane (DCS) used for forming a silicon nitride film is adsorbed onto the wafer by chemical adsorption through the activation of the gas.

To do this, the wafer is heated via the rotary table by a heating part installed below the rotary table, so that the gas discharged from the gas nozzle is heated and activated. Here, specifically describing the activation of the gas, the gas discharged from the gas nozzle is heated by the heat radiated from the rotary table or the wafer while diffusing in the radial direction on the rotary table. At each position on the wafer, the gas is injected from above the respective position. Even if the gas is not yet sufficiently heated, another gas is injected to another position and flows into the respective position. Thus, another gas is also heated and activated while moving the rotary table or the wafer.

Thus, in a central region of the wafer, the gas discharged to a position far from the central region as seen in the radial direction of the rotary table travels a long distance and gets to the central region, so that the gas is activated during the period of time. That is to say, in the central region of the wafer, the gas remains sufficiently activated. On the other hand, at a peripheral portion of the wafer close to the central region of the rotary table, a distance between the peripheral portion of the wafer and an end portion of the gas nozzle is short. Thus, a movement distance at which the gas discharged from the end portion of the gas nozzle travels to the peripheral portion of the wafer is short. This holds true in a peripheral portion of the wafer close to an outer edge side of the rotary table. As a result, at the peripheral portions of the wafer in the radial direction of the rotary table, a film thickness tends to be lower than a film thickness of the central side of the wafer because the activation of the source gas is difficult to be performed sufficiently.

### SUMMARY

Some embodiments of the present disclosure provide a technique for improving the in-plane uniformity of a film thickness by sequentially supplying process gases reacting with each other to a substrate to laminate reaction products on a surface of the substrate.

According to one embodiment of the present disclosure, there is provided a film-forming apparatus for forming a thin film on a substrate by performing, inside a vacuum vessel, a cycle of sequentially supplying a source gas and a reactant gas reacting with the source gas to generate a reaction product a plurality of times, the film-forming apparatus including: a rotary table installed inside the vacuum vessel, and including a substrate mounting region, on which the substrate is mounted, formed at one surface side of the rotary table, the rotary table being configured to rotate the substrate mounting region; a heating part configured to heat the substrate mounted on the rotary table; a first process region in which the source gas is supplied toward the substrate mounting region of the rotary table to perform a first process; a second process region defined apart from the first process region in a circumferential direction of the rotary table via a separation portion, and in which the reactant gas is supplied to perform a second process; and a main nozzle, a central-side auxiliary nozzle and a peripheral-side auxiliary nozzle installed in the first process region to extend in a direction intersecting with a movement path of the rotary table and along a rotational direction of the rotary table, each of the main nozzle, the central-side auxiliary nozzle and the peripheral-side auxiliary nozzle including gas discharge holes formed to discharge the source gas downward in a longitudinal direction thereof, wherein when a central side and a peripheral wall side of the vacuum vessel are respectively defined as an inner side and an outer side, respectively, the gas discharge holes of the main nozzle are formed to face an entire region of a passage region of the substrate when viewed in inward and outward directions and to face inner and outer regions of the passage region of the substrate on the rotary table, the gas discharge holes of the central-side auxiliary nozzle are formed in a region facing the inner region of the passage region of the substrate on the rotary table, the gas discharge holes of the peripheral-side auxiliary nozzle are installed in a region facing the outer region of the passage region of the substrate on the rotary table, and each of the central-side auxiliary nozzle and the peripheral-side auxiliary nozzle is installed to compensate for a shortage of the source gas supplied to an inner peripheral portion and an outer peripheral portion of the substrate from the main nozzle.

According to another embodiment of the present disclosure, there is provided a film-forming method for forming a thin film on a substrate by performing, inside a vacuum vessel, a cycle of sequentially supplying a source gas and a reactant gas reacting with the source gas to generate a reaction product a plurality of times, the film-forming method including: mounting the substrate on one surface side of a rotary table installed inside the vacuum vessel; heating the substrate; and repeatedly performing an operation of supplying and adsorbing the source gas to and onto the substrate by using gas nozzles, which are installed in a first process region and have gas discharge holes formed to discharge the source gas downward in a longitudinal direction, while rotating the substrate on the rotary table, and an operation of supplying, a plurality of times, the reactant gas to the substrate in a second process region separated from the first process region by a separation portion, wherein when a central side and a peripheral wall side of the vacuum vessel are respectively defined as an inner side and an outer side, respectively, in the first process region, an operation of supplying, by a main nozzle, the source gas to an entire region of a passage region of the substrate when viewed in inward and outward directions and each of an inner region and an outer region of the passage region of the substrate on the rotary table, an operation of supplying, by a central-side auxiliary nozzle, the source gas to an inner region of the passage region of the substrate on the rotary table, and an operation of supplying, by a peripheral-side auxiliary nozzle, the source gas to an outer region of the passage region of the substrate on the rotary table are performed.

According to yet another embodiment of the present disclosure, there is provided a non-transitory computer-readable storage medium storing a computer program that is used in a film-forming apparatus for forming a thin film on a substrate, by performing, inside a vacuum vessel, a cycle of sequentially supplying a source gas and a reactant gas reacting with the source gas to generate a reaction product a plurality of times, wherein the computer program incorporates a group of steps so as to execute the aforementioned film-forming method.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional view of a film-forming apparatus according to an embodiment of the present disclosure.

FIG. 2 is a plan view of the film-forming apparatus.

FIGS. 3A and 3B are a perspective view and a cross-sectional view showing a first process region.

FIG. 4 is a plan view showing the first process region.

FIG. 5 is an explanatory view showing the activation of a DCS gas supplied in the first process region.

FIGS. 6A to 6C are explanatory views showing an adsorption amount of a DCS gas supplied in the first process region.

FIG. 7 is a plan view showing another example of a film-forming apparatus according to an embodiment of the present disclosure.

FIG. 8 is a cross-sectional perspective view showing a modified example of a peripheral-side auxiliary nozzle.

FIG. 9 is a cross-sectional view showing a modified example of a peripheral-side auxiliary nozzle.

FIG. 10 is an explanatory view for explaining main nozzles in Experimental Examples 1-1 to 1-3.

FIG. 11 is a characteristic view showing a film thickness distribution of a wafer in an X-axis direction in Experimental Examples 1-1 to 1-3.

FIG. 12 is a characteristic view showing a film thickness distribution of a wafer in a Y-axis direction in Experimental Examples 1-1 to 1-3.

FIG. 13 is an explanatory view for explaining central-side auxiliary nozzles in Experimental Examples 2-1 to 2-3.

FIG. 14 is a characteristic view showing a film thickness distribution of a wafer in a Y-axis direction in Experimental Examples 2-1 to 2-3.

FIG. 15 is a characteristic view showing a film thickness distribution of a wafer in a Y-axis direction in Experimental Examples 2-4 to 2-7.

FIG. 16 is an explanatory view for explaining peripheral-side auxiliary nozzles in Experimental Examples 3-1 to 3-3.

FIG. 17 is a characteristic view showing a film thickness distribution of a wafer in a Y-axis direction in Experimental Examples 3-1 to 3-3.

FIG. 18 is a characteristic view showing a film thickness distribution of a wafer in a Y-axis direction in Experimental Examples 3-4 to 3-7.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

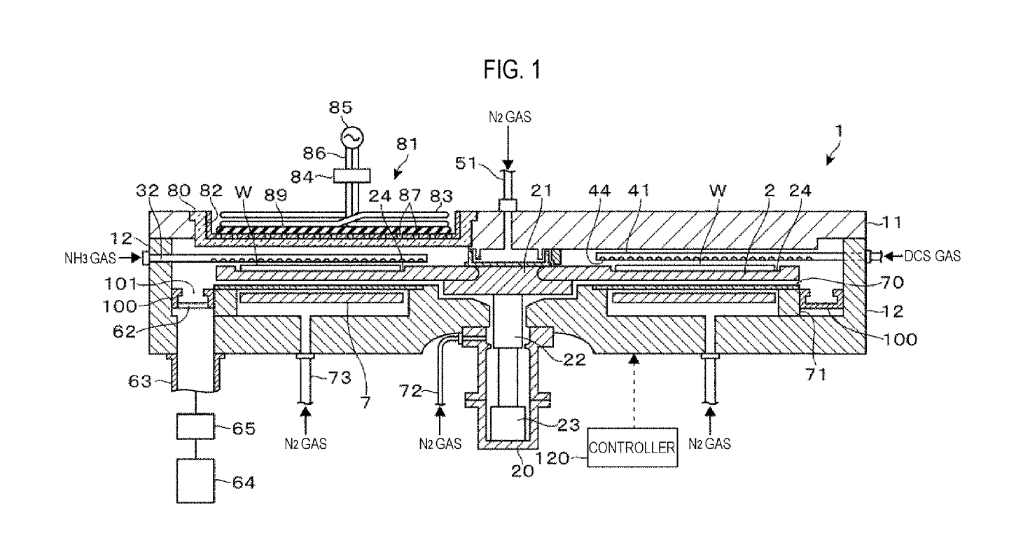

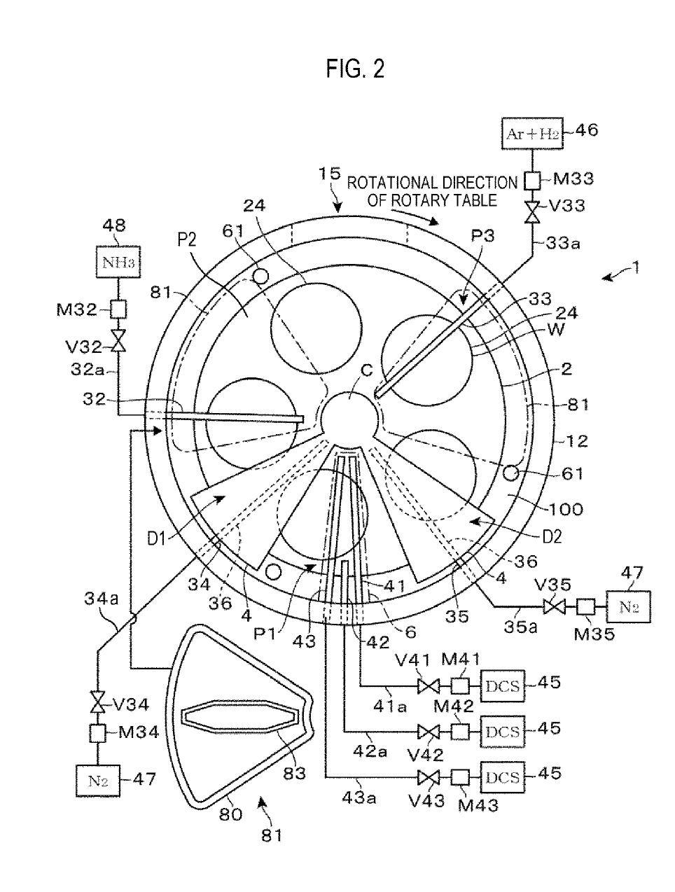

A film-forming apparatus according to an embodiment of the present disclosure will be described. As shown in FIGS. 1 and 2, the film-forming apparatus includes a vacuum vessel 1 having a substantially circular shape in a plan view, and a rotary table 2 installed in the vacuum vessel 1 and rotates a wafer W. The rotary table 2 has a rotational center at the center of the vacuum vessel 1. The vacuum vessel 1 is provided with a ceiling plate 11 and a container body 12. The ceiling plate 11 can be attached to and detached from the container body 12. A separation gas supply pipe 51 which supplies a nitrogen (N₂) gas as a separation gas is connected to a central portion at an upper surface side of the ceiling plate 11 so as to suppress different process gases from being mixed with each other at a central portion in the vacuum vessel 1.

The rotary table 2 is fixed to a substantially cylindrical core portion 21 in a central region C. The rotary table 2 can be rotated around a vertical axis, in this embodiment, in the clockwise direction as viewed from above, by a rotary shaft 22 connected to a lower surface of the core portion 21 and extending in a vertical direction. In FIG. 1, reference numeral 23 denotes a driving part for rotating the rotary shaft 22 around the vertical axis, and reference numeral 20 denotes a case body for accommodating the rotary shaft 22 and the driving part 23. A purge gas supply pipe 72 for supplying a N₂ gas as a purge gas to a region below the rotary table 2 is connected to the case body 20.

As shown in FIGS. 1 and 2, a circular concave portion 24 in which a wafer W having a diameter of, for example, 300 mm is mounted, is formed as a substrate mounting region in a surface portion (upper surface portion) of the rotary table 2. The concave portion 24 is formed at a plurality of (e.g., five) locations along a rotational direction (circumferential direction) of the rotary table 2. The concave portion 24 has a diameter dimension and a depth dimension so that when the wafer W is accommodated in the concave portion 24, a surface of the wafer W and a surface of the rotary table 2 (area where the wafer W is not mounted) are aligned.

Returning to FIG. 1, a heater unit 7 as a heating part is installed over the entire circumference in a space between the rotary table 2 and a bottom surface portion of the vacuum vessel 1. The heater unit 7 heats the wafer W mounted on the rotary table 2 at, for example, 400 degrees C. via the rotary table 2. In FIG. 1, reference numeral 71 denotes a cover member installed at a lateral side of the heater unit 7, and reference numeral 70 denotes a cover member for covering an upper side of the heater unit 7. In addition, a purge gas supply pipe 73 is installed to pass through the bottom surface portion of the vacuum vessel 1 at a plurality of locations below the heater unit 7 in the circumferential direction.

As shown in FIG. 2, a transfer port 15 through which the wafer W is transferred between an external transfer arm (not shown) and the rotary table 2, is formed in a lateral wall of the vacuum vessel 1. The transfer port 15 can be air-tightly opened and closed by a gate valve (not shown). The wafer W is transferred between the external transfer arm and the rotary table 2 at a transfer position facing the transfer port 15 in the concave portion 24 of the rotary table 2. Transfer lifting pins and a lifting mechanism (both not shown) are installed at a location corresponding to the transfer position. The transfer lifting pins pass through the concave portion 24 from below the rotary table 2 to lift up the wafer W from a back surface thereof.

As shown in FIG. 2, at positions facing regions through which the concave portions 24 of the rotary table 2 pass, a modification region P3, a separation gas supply part 35, a first process region P1, a separation gas supply part 34, and a second process region P2 are arranged in this order at intervals in the clockwise direction (rotational direction of the rotary table 2) as viewed from the transfer port 15 and in the circumferential direction (the rotational direction of the rotary table 2) of the vacuum vessel 1.

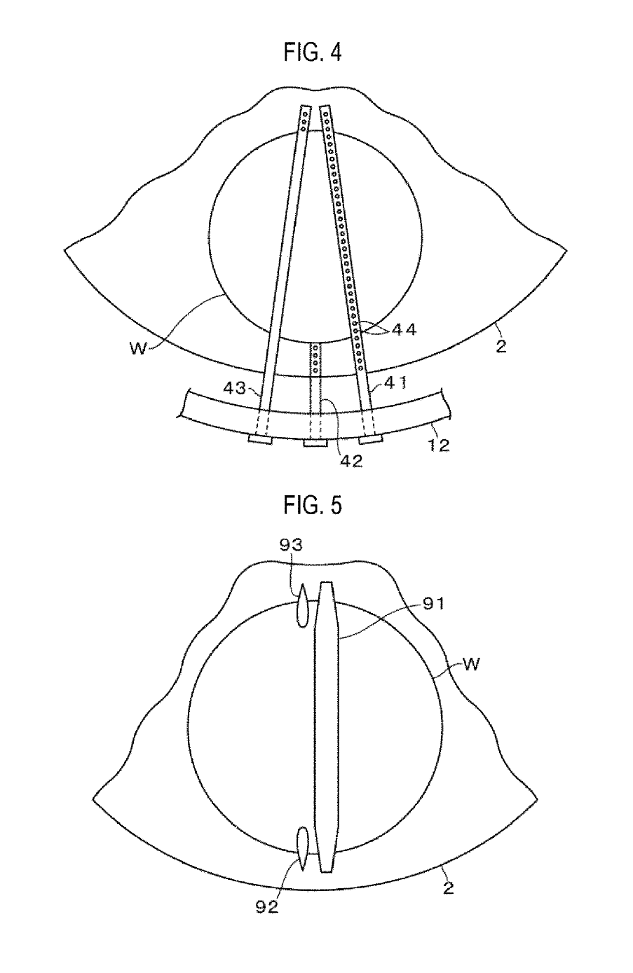

The first process region P1 will be described with reference to FIGS. 2 to 4. In addition, gas discharge holes 44 formed in each nozzle are formed in a lower surface of the respective nozzle. However, for the sake of convenience in description, the gas discharge holes 44 are shown to be formed in an upper surface of the nozzle in FIG. 4. A main nozzle 41, a peripheral-side auxiliary nozzle 42, and a central-side auxiliary nozzle 43 which respectively supply a DCS gas as the process gas, are sequentially installed in the first process region P1 from an upstream side in the rotational direction. These nozzles are installed to extend horizontally while facing the substrate mounting region of the rotary table 2.

The main nozzle 41, which extends from an outer peripheral wall of the vacuum vessel 1 toward the central region C, is installed to stride over a passage region through which the wafer W passes when the rotary table 2 is rotated. The main nozzle 41 is formed in a cylindrical shape whose distal end is sealed. A plurality of gas discharge holes 44 is formed in a lower surface of the main nozzle 41. The plurality of gas discharge holes 44 is aligned at equal intervals in the longitudinal direction in a range from a position of 26 mm, which is a distance from an outer peripheral edge of the passage region of the wafer W to an outer peripheral side of the rotary table 2, to a position of 24 mm, which is a distance from an inner peripheral edge of the passage region of the wafer W to a rotational central side of the rotary table 2.

The peripheral-side auxiliary nozzle 42 is installed at a position adjacent to the main nozzle 41 at the downstream side in the rotational direction of the rotary table 2. The peripheral-side auxiliary nozzle 42 compensates for the supply of gas from the main nozzle 41 to a peripheral portion of the wafer W at an outer edge side of the rotary table 2. The peripheral-side auxiliary nozzle 42 extends from the outer peripheral wall of the vacuum vessel 1 toward the central region C in a range outward of the passage region of the wafer W on the rotary table 2. The peripheral-side auxiliary nozzle 42 is formed in a cylindrical shape whose distal end is sealed. A plurality of another gas discharge holes 44 is formed at equal intervals in a lower surface of the peripheral-side auxiliary nozzle 42 in the longitudinal direction. The plurality of another gas discharge holes 44 is formed over a length region from several millimeters to several tens of millimeters which faces an outer region of the rotary table 2 rather than the passage region of the wafer W on the rotary table 2.

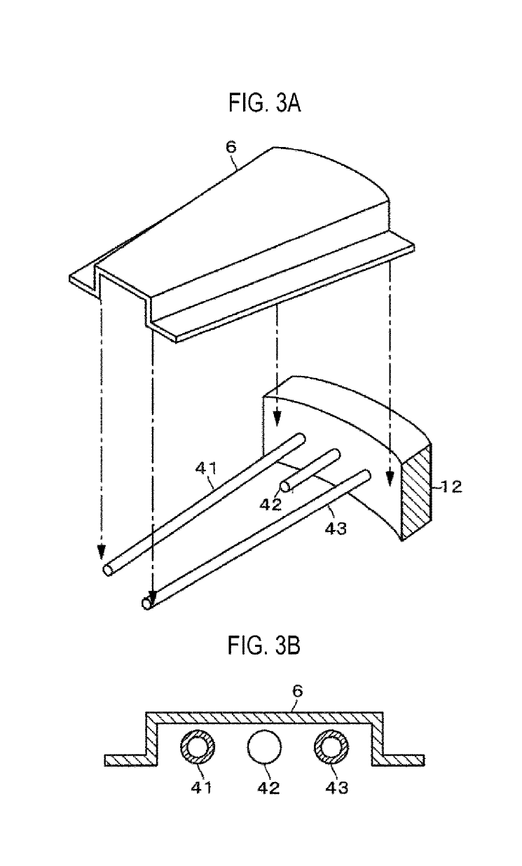

The central-side auxiliary nozzle 43 is installed at a position adjacent to the peripheral-side auxiliary nozzle 42 at the downstream side in the rotational direction of the rotary table 2. The central-side auxiliary nozzle 43 compensates for the supply of gas from the main nozzle 41 to the peripheral portion of the wafer W at the side of the central region C of the rotary table 2. The central-side auxiliary nozzle 43 is installed to extend from the outer peripheral wall of the vacuum vessel 1 toward the central region C and stride over the passage region of the wafer W on the rotary table 2. The central-side auxiliary nozzle 43 is formed in a cylindrical shape whose distal end is sealed. A plurality of another gas discharge holes 44 is formed at equal intervals in a lower surface of the distal end side of the central-side auxiliary nozzle 43 in the longitudinal direction in a length region from several millimeters to several tens of millimeters which faces the central region of the vacuum vessel 1 rather than the inner peripheral edge of the passage region of the wafer W on the rotary table 2. In addition, FIG. 3A is an exploded perspective view of the first process region P1, and FIG. 3B is a cross-sectional view of the first process region P1. In the first process region P1, there is installed a nozzle cover 6 having a hat shape in cross-section that covers the main nozzle 41, the peripheral-side auxiliary nozzle 42, and the central-side auxiliary nozzle 43 from above in the longitudinal direction. The nozzle cover 6 is made of, for example, quartz. A gap is formed between an upper surface of the nozzle cover 6 and the ceiling plate 11 so that a portion of the separation gas flowing out from the separation gas supply parts 34 and 35 does not enter below the nozzle cover 6.

Base end sides of the main nozzle 41, the peripheral-side auxiliary nozzle 42, and the central-side auxiliary nozzle 43 are respectively connected to gas supply pipes 41a to 43a which pass through the vacuum vessel 1, and subsequently, are connected to respective DCS gas supply sources 45 via respective valves V41 to V43. In addition, each of the DCS gas supply sources 45 also supplies a mixed gas of DCS and N₂ gas as a carrier gas, but is referred to as a DCS gas supply source for the sake of convenience. In the figures, M41 to M43 are flow rate controllers.

An ammonia (NH₃) gas supply nozzle 32 configured similarly to the main nozzle 41 is installed in the second process region P2. A base end side of the NH₃ gas supply nozzle 32 is connected to a gas supply pipe 32a passing through the vacuum vessel 1 and subsequently, is connected to an NH₃ gas supply source 48 which supplies an NH₃ gas. A plasma generating part 81 for changing the NH₃ gas discharged from the NH₃ gas supply nozzle 32 into plasma is installed above the second process region P2.

As shown in FIGS. 1 and 2, the plasma generating part 81 is configured by winding antennas 83 made of, for example, a metal wire, in a coil shape, and housed in a housing 80 made of, for example, quartz or the like. Each of the antennas 83 is coupled to a high frequency power source 85 having a frequency of, for example, 13.56 MHz and an output power of, for example, 5,000 W, by a connection electrode 86 in which a matching device 84 is installed. In the figure, reference numeral 82 denotes a Faraday shield for shielding an electric field generated from a high frequency generating part, and reference numeral 87 denotes a slit for allowing the magnetic field generated from the high frequency generating part to reach the wafer W. Further, reference numeral 89 indicated between the Faraday shield 82 and the antenna 83 denotes an insulating plate.

A plasma process gas nozzle 33 configured similarly to the main nozzle 41 is installed in the modification region P3. A base end side of the plasma process gas nozzle 33 is connected to a gas supply pipe 33a passing through the vacuum vessel 1 and subsequently, is connected to a mixed gas supply source 46 which supplies a mixed gas of an argon (Ar) gas and a hydrogen (H₂) gas. The plasma generating part 81 for converting the Ar gas and the H₂ gas discharged from the plasma process gas nozzle 33 into plasma is installed above the modification region P3, similarly to the second process region P2.

Each of the two separation gas supply parts 34 and 35 are configured by a nozzle similarly to the main nozzle 41. Base end sides of the separation gas supply parts 34 and 35 are respectively connected to gas supply pipes 34a and 35a which pass through the vacuum vessel 1 and subsequently, are connected to respective N₂ gas supply sources 47. As shown in FIG. 2, a convex portion 4 having a substantially fan-like planar shape is formed above each of the separation gas supply parts 34 and 35. Each of the separation gas supply parts 34 and 35 is accommodated in a groove 36 formed in the convex portion 4. The N₂ gas discharged from the separation gas supply part 34 diffuses from the separation gas supply part 34 to both sides in the circumferential direction of the vacuum vessel 1, so that a first separation region D1 for separating the atmosphere of the first process region P1 side from the atmosphere of the second process region P2 side is defined. In addition, the N₂ gas discharged from the separation gas supply part 35 diffuses from the separation gas supply part 35 to both sides in the circumferential direction of the vacuum vessel 1, so that a second separation region D2 for separating the atmosphere of the modification region P3 side and the atmosphere of the first process region P1 side is defined.

Therefore, the separation gas supply part 35 is installed between the modification region P3 and the first process region P1 when viewed from the upstream side in the rotational direction of the rotary table 2, and the separation gas supply part 34 is installed between the first process region P1 and the second process region P2 when viewed from the upstream side in the rotational direction of the rotary table 2. Further, the separation gas supply part 35 is installed between the second process region P2 and the first process region P1 when viewed from the upstream side in the rotational direction of the rotary table 2.

As shown in FIGS. 1 and 2, a side ring 100 as a cover body, which includes a gas flow pass 101 as a groove portion formed therein, is installed at a position slightly lower than the rotary table 2 in the outer peripheral side of the rotary table 2. In an upper surface of the side ring 100, exhaust ports 61 are respectively formed at three locations such as a downstream side of the first process region P1, a downstream side of the second process region P2, and a downstream side of the modification region P3 so as to be spaced apart from each other in the circumferential direction. As shown in FIG. 1, these exhaust ports 61 are respectively coupled to, for example, a vacuum pump 64 as a vacuum exhaust mechanism through an exhaust pipe 63 in which a pressure adjusting part 65 such as a butterfly valve is installed.

In addition, the film-forming apparatus is provided with a controller 120 composed of a computer for controlling the entire operations of the apparatus. A program for performing a film-forming process to be described later is stored in a memory of the controller 120. This program includes a group of steps so as to execute operations of the apparatus to be described later, and is installed by a storage medium such as a hard disk, a compact disk, a magneto-optical disk, a memory card, a flexible disk, or the like.

The operation of the above-described embodiment will be described. In addition, in the specification, for the sake of convenience in description, a direction from an outer wall of the vacuum vessel 1 to the central region C is referred to as an Y-axis direction, and a direction orthogonal to the Y-axis direction, that is to say, a direction in which the wafer W moves when the rotary table 2 is rotated is referred to as an X-axis direction. First, the gate valve is opened and, for example, five wafers W are transferred into the vacuum vessel 1 via the transfer port 15 by the transfer arm while the rotary table 2 is intermittently rotated. Subsequently, the five waters W are mounted on the rotary table 2 with an elevation operation of the above-described lifting pins (not shown). Subsequently, the gate valve is closed and the interior of the vacuum vessel 1 is evacuated by the vacuum pump 64 and the pressure adjusting part 65. In addition, the wafers W are heated at, for example, 400 degrees C. by the heater unit 7 while the rotary table 2 is rotated in the clockwise direction at a rotational speed of, for example, 10 rpm.

Subsequently, a mixed gas having a flow rate of 1,500 sccm in which a DCS gas having a flow rate of, for example, 1,000 sccm and a N₂ gas serving as a carrier gas having a flow rate of 500 sccm are mixed, is supplied from the main nozzle 41 in the first process region P1. In addition, a DCS gas is supplied from the peripheral-side auxiliary nozzle 42 at a flow rate of, for example, 20 sccm, and a DCS gas is supplied from the central-side auxiliary nozzle 43 at a flow rate of, for example, 20 sccm. In addition, in the specification, the mixed gas of the DCS gas and the N₂ gas is also described as a DCS gas for the sake of convenience in description. However, in the description of the flow rate of the gas discharged from the nozzle, it is assumed that, unless specifically mentioned otherwise that the DCS gas is a mixed gas, only the DCS gas is supplied.

In addition, an NH₃ gas is discharged into the second process region P2 at a flow rate of, for example, 100 sccm, and a mixed gas of the Ar gas and the H₂ gas is discharged from the modification region P3 at a flow rate of, for example, 10,000 sccm. In addition, a separation gas is discharged from the separation gas supply part 34 at a flow rate of, for example, 5,000 sccm and a N₂ gas is discharged from the separation gas supply pipe 51 and the purge gas supply pipes 72 and 73 at a predetermined flow rate. Then, the interior of the vacuum vessel 1 is adjusted to have a pressure of, for example, 100 Pa, by the pressure adjusting part 65. Further, in the plasma generating part 81, the high-frequency electric power of, for example, 1,500 W, is supplied to each antenna 83. As a result, the gases supplied below the plasma generating part 81 are respectively activated by virtue of the magnetic field passed through the slits 87. Thus, plasma such as ions and radicals is generated.

Subsequently, the rotary table 2 is rotated at a rotation speed of, for example, 10 rpm. The following description will be primarily focused on a single wafer W. First, the wafer W enters the first process region P1 and sequentially passes in front of the main nozzle 41, the peripheral-side auxiliary nozzle 42, and the central-side auxiliary nozzle 43. Although the DCS gas discharged from the gas discharge holes 44 of the main nozzle 41 remains not sufficiently heated immediately after the discharge, the DCS gas rises in temperature by the heat radiated from the rotary table 2 or the wafer W while diffusing in the radial direction on the rotary table 2 and gets activated. This phenomenon occurs in the entire area below the main nozzle 41. Active species which has an amount corresponding to the total amount of gas entering from another position and the sufficiently heated gas, exist at each position of the wafer W as viewed in the radial direction on the wafer W. That is to say, for a certain position on the wafer W, the degree of activation (the amount of the active species) at the respective position is influenced by an arrival path of the gas until the gas reaches the respective position.

Therefore, since the DCS gas discharged from the main nozzle 41 reaches a peripheral side of the wafer W when viewed in the radial direction of the rotary table 2, the DCS gas in the central portion of the wafer W is sufficiently activated. On the other hand, for the DCS gas discharged to the central portion of the wafer W from the main nozzle 41, it can be said that the arrival path of the DCS gas until the gas reaches the peripheral portion of the wafer W is long at the peripheral portion of the wafer W close to the central side of the rotary table 2. However, an end portion of the arrangement region of the gas discharge holes 44 of the main nozzle 41, which is located farthest from the peripheral portion of the wafer W in the vicinity of the central side of the rotary table 2, is close to the peripheral portion of the wafer W. Thus, an arrival path along which the DCS gas discharged from the end portion of the arrangement region reaches the peripheral portion of the wafer W is shorter than an arrival path to the central side of the rotary table 2 from the end portion of the arrangement region. This may hold true in the peripheral portion of the wafer W close to the outer edge side of the rotary table 2. As a result, focusing on only to the main nozzle 41, the degree of activation of the DCS gas is smaller at the peripheral portion of the wafer W than that at the central portion of the wafer W.

On the other hand, an arrangement region of the gas discharge holes 44 of the central-side auxiliary nozzle 43 is formed above the rotary table 2 closer to the central region C than the wafer W. Thus, the gas discharged from the gas discharge holes 44 diffuses and reaches the peripheral portion of the wafer W. An arrival path through which the DCS gas discharged from the central-side auxiliary nozzle 43 reaches the peripheral portion of the wafer W is short and the degree of activation in the respective peripheral portion is not large, that is to say, an amount of the activated DCS gas is not large. This compensates for the shortage of the amount of the active species of the DCS gas at the peripheral portion of the wafer W with respect to the central portion thereof, which occurs when only the main nozzle 41 is used.

Similarly, the DCS gas discharged from the peripheral-side auxiliary nozzle 42 compensates for the shortage of the amount of the active species of DCS gas at the peripheral portion of the wafer W in the outer edge side of the rotary table 2. In this way, in the first process region P1, the DCS gas is supplied to the wafer W in a state of being activated with the good uniformity in the radial direction (the Y-axis direction) of the rotary table 2, and adsorbed onto the wafer W.

FIG. 5 schematically shows the distribution of the amount of the active species of the DCS gas discharged from the nozzles 43, 41 and 42 as widths of strip-shaped portions 91 to 93. In FIG. 5, the strip-shaped portion 91 located at the central portion represents the distribution of the amount of active species of the DCS gas discharged from the main nozzle 41, the strip-shaped portion 92 located at the outer edge side of the rotary table 2 represents the distribution of the amount of active species of the DCS gas discharged from the peripheral-side auxiliary nozzle 42, and the strip-shaped portion 93 located at the central side of the rotary table 2 represents the distribution of the amount of active species of the DCS gas discharged from the central-side auxiliary nozzle 43.

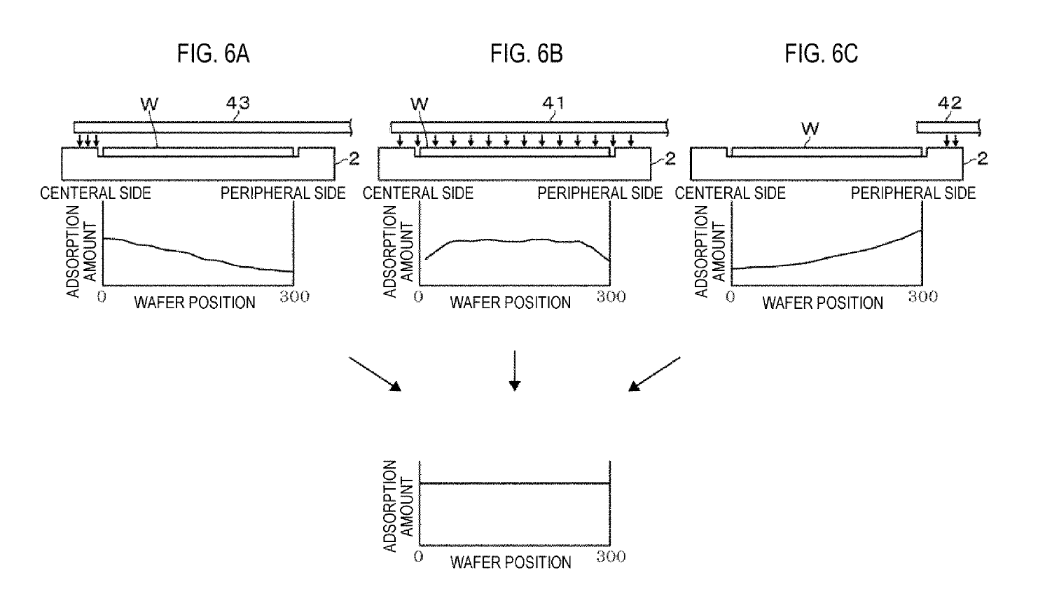

Therefore, when the wafer W passes through the three nozzles of the central-side auxiliary nozzle 43, the peripheral-side auxiliary nozzle 42, and the main nozzle 41, the DCS gas supplied from each of the nozzles 41 to 43 is adsorbed onto the wafer W. FIG. 6 schematically shows an adsorption amount of the DCS gas supplied from each of the central-side auxiliary nozzle 43, the peripheral-side auxiliary nozzle 42, and the main nozzle 41 in the wafer W. As shown in FIG. 6B, the adsorption amount of the DCS gas supplied from the main nozzle 41 decreases both in a region of the rotational central side of the rotary table 2 and a region close to the outer edge side of the rotary table 2 in the wafer W. On the other hand, as shown in FIG. 6A, a large amount of the DCS gas supplied from the central-side auxiliary nozzle 43 is adsorbed onto the wafer W at the rotational central side of the rotary table 2. Further, as shown in FIG. 6C, a large amount of the DCS gas supplied from the peripheral-side auxiliary nozzle 42 is adsorbed onto the wafer W in a region close to the outer edge of the rotary table 2. Accordingly, as the wafer W passes through the three nozzles 41 to 43, the adsorption amounts of the DCS gas supplied from the nozzles 41 to 43 are combined with each other on the wafer W so that the uniformity of the adsorption amount of the DCS gas in the Y-axis direction of the wafer W is improved.

Then, the wafer W onto which the DCS gas is adsorbed in the first process region P1 enters the second process region P2 with the rotation of the rotary table 2. The DCS gas adsorbed onto the wafer W is nitrided by the plasma of the NH₃ gas so that one or more molecular layers of a silicon nitride film (SiN film) which is a thin film component are formed, thus generating reaction products.

Then, by further rotating the rotary table 2, the wafer W enters into the modification region P3 where the plasma collides with the surface of the wafer W, for example, impurities are released from the SiN film as HCl, organic gas, or the like, or elements in the SiN film are rearranged, so that densification (high density) of the SiN film is achieved. By continuing the rotation of the rotary table 2 in this manner, the adsorption of the DCS gas onto the surface of the wafer W, the nitridation of the components of the DCS gas adsorbed onto the surface of the wafer W, and the plasma modification of the reaction products are performed multiple times in this order, so that the reaction products are laminated to form a thin film.

According to the above-described embodiment, the film forming-apparatus for forming the SiN film on the wafer W by performing, multiple times, a cycle in which the wafer W rotated by the rotary table 2 is heated and the DCS gas and the NH₃ gas are sequentially supplied to the wafer W inside the vacuum vessel 1, is configured as follows. Specifically, the main nozzle 41 that extends from a peripheral wall of the vacuum vessel 1 toward the center of the rotary table 2 and supplies the DCS gas to the wafer W in the radial direction is installed to supply the DCS gas to the wafer W. Further, the peripheral-side auxiliary nozzle 42 which supplies the DCS gas to a region defined at the outer peripheral side of the rotary table 2 rather than the passage region of the wafer W in the rotary table 2 is installed. The central-side auxiliary nozzle 43 which supplies supply the DCS gas to a region defined at the central side of the rotary table 2 rather than the passage region of the wafer W is installed. Therefore, as described in detail above, when the DCS gas is supplied from the main nozzle 41, the degree of activation of the DCS gas decreases as viewed in the radial direction of the rotary table 2. That is to say, the activated DCS gas is supplied to both ends of the wafer W where the adsorption amount of the DSC gas becomes insufficient. Therefore, the in-plane uniformity of a film thickness of the film formed on the wafer W is improved.

Further, the adsorption of the DCS gas onto the wafer W requires heating and activating the DCS gas. To do this, the peripheral-side auxiliary nozzle 42 and the central-side auxiliary nozzle 43 are installed such that the gas discharge holes 44 thereof are arranged spaced apart from the passage region of the wafer W. The DCS gas is heated while diffusing and moving from outside the wafer so that the adsorption amount of the DCS gas increases at the inner and outer circumferential sides of the rotary table 2 on the wafer W.

It was found by the inventors of the present disclosure that, focusing on the distribution of the adsorption amount of the DCS gas onto the surface of the wafer W in the Y-axis direction when the DCS gas is supplied from the main nozzle 41, the adsorption amount of the DCS gas at the central side of the rotary table 2 was the smallest at the end portion of the central side of the rotary table 2.

Therefore, the distribution of the adsorption amount of the DCS gas by the central-side auxiliary nozzle 43 in the Y-axis direction may be adjusted such that the adsorption amount of the DCS gas is maximized at the peripheral side of the wafer W in the central side of the rotary table 2.

As shown in a verification test 2 to be described later, the gas discharge holes 44 are arranged at a position close to the central side of the rotary table 2 from the inner peripheral edge of the passage region of the wafer W such that the DCS gas is supplied from the gas discharge holes 44. It is therefore possible to obtain a maximum value of the adsorption amount of the DCS gas at a position close to the central side of the rotary table 2 in the periphery of the wafer W in the distribution of the adsorption amount of the DCS gas along the Y-axis direction. In some embodiments, a range in which the gas discharge holes 44 are arranged may set to a range of about 8 to 26 mm from the inner peripheral edge of the passage region of the wafer W to the central side of the rotary table 2.

In addition, as a flow velocity of the DCS gas discharged from the central-side auxiliary nozzle 43 becomes slower or a partial pressure of the DCS gas becomes higher (as a value (the flow rate of the DCS gas/the flow rate of the DCS gas+the flow rate of the carrier gas) becomes larger), the DCS gas tends to stay at a discharge position on the rotary table 2. Accordingly, a period of time until the DCS gas diffuses to the wafer W becomes longer, so that the activity tends to increase to cause the DCS gas to be easily adsorbed onto the wafer W. Therefore, by forming the gas discharge holes 44 in the central-side auxiliary nozzle 43 over an extent covering from the inner peripheral edge of the passage region of the wafer W to the central side of the rotary table 2, it is possible to maximize the adsorption amount of the DCS at a position close to the peripheral edge of the central side of the rotary table 2.

Therefore, as shown in a verification test 2 to be described later, a flow velocity of the DCS gas supplied from the central-side auxiliary nozzle 43 may be set to 40 sccm or less, specifically, 10 to 30 sccm. Thus, the adsorption amount of the DCS gas by the central-side auxiliary nozzle 43 in the Y-axis direction may be distributed such that the adsorption amount of the DCS gas is maximized at a position close to the central side of the rotary table 2 in the peripheral edge of the wafer W. Thus, by compensating for the shortage of the DCS gas supplied from the main nozzle 41, it is possible to equalize the adsorption amount of the DCS gas at the position close to the central side of the rotary table 2 in the peripheral edge of the wafer W.

Similarly, it was found that, in the distribution of the adsorption amount of the DCS gas onto the surface of the wafer W in the Y-axis direction, the adsorption amount of the DCS gas at a position close to the outer edge side of the rotary table 2 in the surface of the wafer W was the smallest at an end portion close to the outer edge side of the rotary table 2 in the wafer W.

As shown in a verification test 3 to be described later, the gas discharge holes 44 are formed in the peripheral-side auxiliary nozzle 42 over an extent covering from the outer peripheral edge of the passage region of the wafer W to the outer edge side of the rotary table 2, thus supplying the DCS gas. Therefore, in the distribution of the adsorption amount of the DCS gas in the Y-axis direction, it is possible to obtain a maximum value of the adsorption amount of the DCS gas at a peripheral edge close to the outer edge side of the rotary table 2 in the wafer W. In some embodiments, a range in which the gas discharge holes 44 are formed may be a range of about 9 to 28 mm from the outer peripheral edge of the passage region of the wafer W to the outer edge side of the rotary table 2.

In addition, even in the peripheral-side auxiliary nozzle 42, as a flow velocity of the discharged gas becomes slower or a partial pressure of the gas becomes higher, the DCS gas tends to stay and tends to be adsorbed onto the wafer W, so that the maximum value of the adsorption amount of the DCS gas may be obtained at the peripheral edge close to the outer edge side of the rotary table 2 in the wafer W. To achieve the above, a flow rate of the DCS gas may be 40 sccm or less, specifically 10 to 30 sccm.

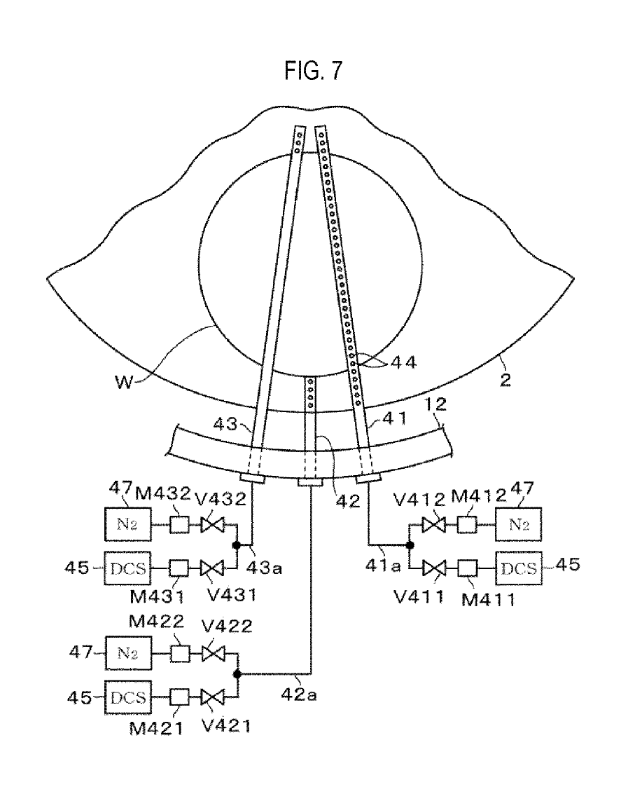

In addition, by adjusting a flow rate ratio of the DCS gas and the carrier gas discharged from the peripheral-side auxiliary nozzle 42 and the central-side auxiliary nozzle 43 as described above, the film thickness distribution of a film formed by a film-forming gas discharged from each of the peripheral-side auxiliary nozzle 42 and the central-side auxiliary nozzle 43 changes. In this regard, the concentration of the DCS gas supplied from the main nozzle 41, the peripheral-side auxiliary nozzle 42, and the central-side auxiliary nozzle 43 may be adjusted. For example, as shown in FIG. 7, the other end side of the gas supply pipe 41a whose one end is connected to the main nozzle 41 is branched. One branched end of the gas supply pipe 41a is coupled to the DCS gas supply source 45 via a valve V411 and a flow rate adjuster M411. In addition, the other branched end of the gas supply pipe 41a is coupled to an N₂ gas supply source 47 via a valve V412 and a flow rate adjuster M412. Similarly, a gas supply pipe 42a is connected to the peripheral-side auxiliary nozzle 42 at one end thereof. The other end of the gas supply pipe 42a is branched. The branched ends are connected to the DCS gas supply source 45 and the N₂ gas supply source 47. A gas supply pipe 43a is connected to the central-side auxiliary nozzle 43 at one end thereof. The other end of the gas supply pipe 43a is branched. The branched ends are connected to the DCS gas supply source 45 and the N₂ gas supply source 47. In addition, in FIG. 7, reference numerals V421, V422, V431, and V432 denote valves, and reference numerals M421, M422, M431, and M432 denote flow rate adjusters.

By configuring as the above and adjusting each of the flow rate adjusters M411, M412, M421, M422, M431 and M432, and the valves V411, V412, V421, V422, V431 and V432, it is possible to adjust the concentration of the DCS gas supplied from each of the main nozzle 41, the peripheral-side auxiliary nozzle 42, and the central-side auxiliary nozzle 43. Accordingly, the film thickness distribution of the film formed by the gas supplied from the main nozzle 41, the film thickness distribution of the film formed by the gas supplied from the peripheral-side auxiliary nozzle 42, and the film thickness distribution of the film formed by the gas supplied from the central-side auxiliary nozzle 43 may be respectively changed. It is therefore possible to adjust the uniformity of the film thickness distribution of the film formed on the wafer W.

A modified example of the peripheral-side auxiliary nozzle 42 will be described. When the rotary table 2 is rotated, a region at a peripheral wall side of the vacuum vessel 1 has a faster movement speed than the central side. As such, the supplied gas is likely to be cooled and the activity tends to deteriorate. Accordingly, the region of the wafer W in the vicinity of the peripheral wall side of the vacuum vessel 1 is likely to be decreased in the adsorption amount. Thus, the DCS gas supplied from the peripheral-side auxiliary nozzle 42 may be supplied after increasing the activity thereof.

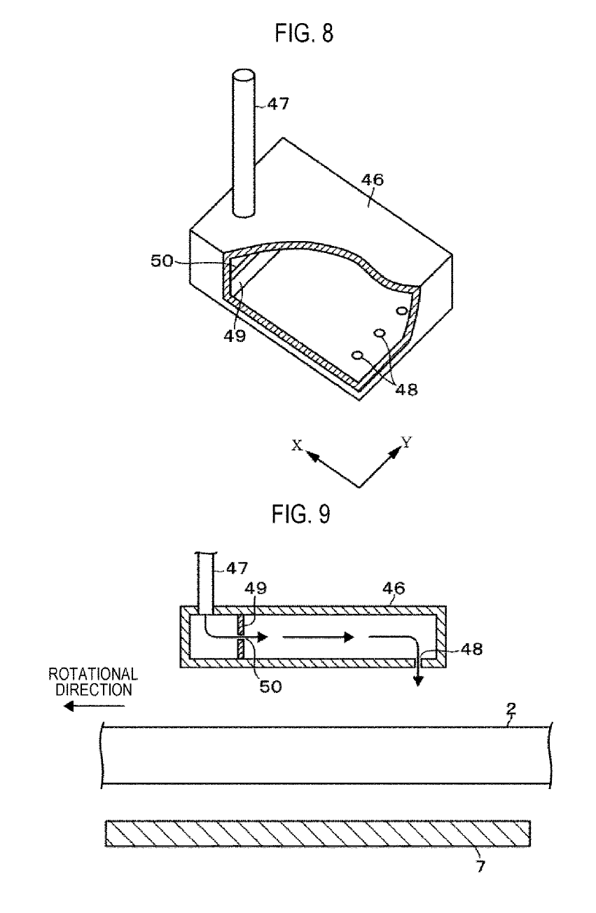

For example, as shown in FIGS. 8 and 9, the peripheral-side auxiliary nozzle 42 includes a rectangular flat gas chamber 46. The gas chamber 46 is disposed to face the rotary table 2. The gas supply pipe 47 for supplying the DCS gas is connected to an upper surface of the gas chamber 46 at an upstream-side peripheral portion of the rotary table 2 in the rotational direction. A plurality of gas discharge holes 48 is formed along the radial direction of the rotary table 2 in a lower surface of the gas chamber 46 at a downstream-side peripheral portion of the rotary table 2 in the rotational direction. A partition wall 49 is installed in the vicinity of the gas supply pipe 47 in the gas chamber 46. A longitudinally-extended slit 50 is formed in the partition wall 49.

In the case of using the peripheral-side auxiliary nozzle 42 configured as above, the DCS gas supplied from the gas supply pipe 47 into the gas chamber 46 is heated by the heater unit 7 until the DCS gas passes through the slit 50 and is then discharged from the gas discharge holes 48 inside the gas chamber 46. Therefore, the DCS gas may be supplied to the wafer W with the DCS gas heated to increase the activity thereof. It is therefore possible to quickly adsorb the DCS gas onto the wafer W even in the region of the wafer W in the vicinity of the peripheral wall side of the vacuum vessel 1. In addition, a heating part may be installed in, for example, the gas chamber 46 in the peripheral-side auxiliary nozzle 42. Further, the central-side auxiliary nozzle 43 and the main nozzle 41 may employ the same structure as that of the peripheral-side auxiliary nozzle 42 shown in FIGS. 8 and 9.

As the film-forming apparatus of the present disclosure, for example, a silicon oxide film forming apparatus which uses BTBAS (bistertiarybutylaminosilane) as a source gas and supplies an oxygen (O₂) gas instead of the NH₃ gas, or a titanium nitride film forming apparatus which uses a TiCl₄ gas as a source gas and a NH₃ gas as a reactant gas may be used. In addition, the film-forming apparatus may include a rotation mechanism for rotating each of the wafers W mounted on the rotary table 2. Since the film thickness can be made uniform in both the X-axis direction and the Y-axis direction of the wafer W, the in-plane uniformity of the film thickness is improved when the wafer W is rotated to form a film.

### [Verification Test 1]

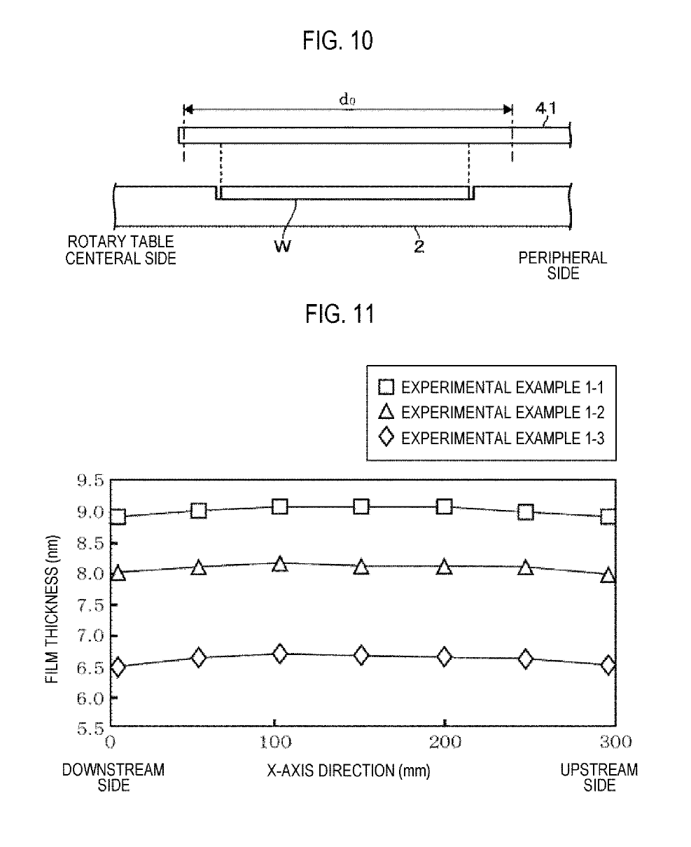

The following test was conducted to verify the effect of the present disclosure. The film-forming apparatus according to the above-described embodiment was used to supply a DCS gas only by the main nozzle 41 and perform a film-formation process on the wafer W. As shown in FIG. 10, in the main nozzle 41, the gas discharge holes 44 were arranged over a range d₀ including a section of 24 mm, from an inner peripheral edge close to the central side of the rotary table 2 in the passage region of the wafer W to the central side of the rotary table 2, and a section of 26 mm from an outer peripheral edge close to the peripheral wall side of the vacuum vessel 1 in the passage region of the wafer W to the peripheral wall side of the vacuum vessel 1. An example in which a mixed gas of the DCS gas having a flow rate of 1,000 sccm and the N₂ gas having a flow rate of 500 sccm was supplied from the main nozzle 41 is designated as Experimental Example 1-1. In addition, an example in which a mixed gas of the DCS gas having a flow rate of 600 sccm and the N₂ gas having a flow rate of 900 sccm was supplied from the main nozzle 41 is designated as Experimental Example 1-2, and an example in which a mixed gas of the DCS gas having a flow rate of 300 sccm and the N₂ gas having a flow rate of 1,200 sccm was supplied from the main nozzle 41 is designated as Experimental Example 1-3.

A heating temperature of the wafer W was set to 400 degrees C., a process pressure was set to 100 Pa, and flow rates of the Ar gas, the H₂ gas, and the NH₃ gas were set to 2,000 sccm, 600 sccm, and 300 sccm, respectively. The rotary table 2 was rotated at a rotational speed of 10 rpm and a cycle of the film-forming process shown in the embodiment was repeated 139 times to form a SiN film, and film thickness distribution of the SiN film formed on the wafer W was investigated in each of Experimental Examples 1-1 to 1-3.

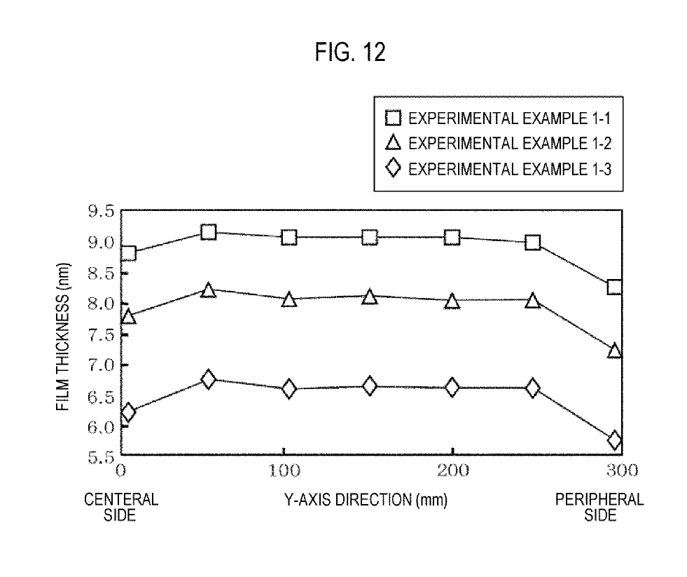

FIG. 11 shows the results of the investigation. The results show the film thickness (nm) of the SiN film on the diameter of the wafer W in a direction (the X-axis direction: a downstream side in the rotational direction of the wafer W is defined at 0 mm) orthogonal to the main nozzle 41 in each of Experimental Examples 1-1 to 1-3. In addition, FIG. 12 shows the film thickness (nm) of the SiN film on the diameter of the wafer W in a direction (the Y-axis direction) in which the main nozzle 41 extends in each of Experimental Examples 1-1 to 1-3. Further, the in-plane uniformity (%: ±[(maximum value of measured value−minimum value of measured value)/(average value of measured value×2)]×100) was obtained by each measured value in the X-axis direction and the Y-axis direction.

As shown in FIGS. 11 and 12, the in-plane uniformity of Experimental Examples 1-1 to 1-3 was at a low level of 0.99%, 1.17%, and 1.65%, respectively, in the direction (the X-axis direction) orthogonal to the main nozzle 41, resulting in exhibiting the good in-plane uniformity of the film thickness. However, the in-plane uniformity of Experimental Examples 1-1 to 1-3 was at a high level of 5.46%, 6.01%, and 7.81%, respectively, in the Y-axis direction in which the main nozzle 41 extends, resulting in exhibiting the poor in-plane uniformity of the film thickness.

As shown in FIGS. 11 and 12, even in both the X-axis direction and the Y-axis direction, the film thickness was thickest in Experimental Example 1-1, and the film thickness was thicker in the order of Experimental Example 1-2 and Experimental Example 1-3.

As shown in FIG. 12, in the Y-axis direction, in all Experiment Examples 1-1 to 1-3, the film thickness of a portion of the wafer W at the outer peripheral side of the film-forming apparatus was thinner at a level of about 1 nm than the central-side portion of the wafer W. Further, in all Experimental Examples 1-1 to 1-3, the film thickness of a portion of the wafer W at the central side of the rotary table 2 was thinner at a level of about 0.5 nm than the central-side portion of the wafer W.

According to these results, it can be said that the film thickness becomes thicker depending on the concentration of the DCS gas. As a result, the NH₃ gas was sufficiently supplied, and the film thickness of the SiN film is not limited by a rate-limitation caused by the shortage of the NH₃ gas. Therefore, it is considered that the film thickness is determined by a difference in the adsorption amount of the DCS gas onto the wafer W, and the adsorption amount is changed by the partial pressure of DCS.

### [Verification Test 2]

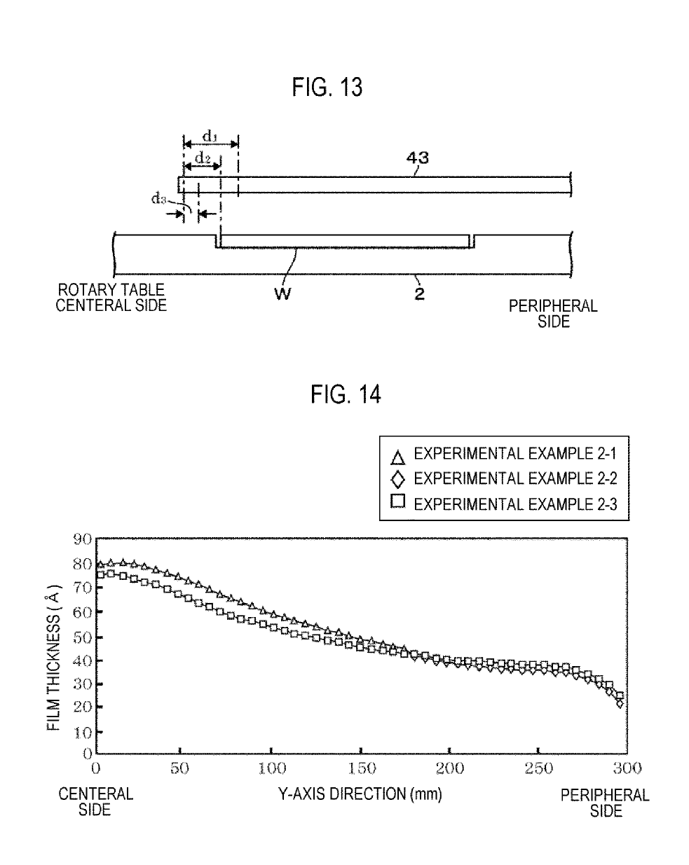

The following test was conducted to investigate the film thickness distribution of a film formed on the wafer W, depending on the position of the gas discharge holes 44 formed in the central-side auxiliary nozzle 43 and the flow rate of the discharged DCS gas. As shown in FIG. 13, an example in which 92 gas discharge holes 44 were formed in a range d1 covering the section of 44 mm which includes the section of 24 mm from a position of an inner peripheral edge of the wafer W close to the central side of the rotary table 2 in the central-side auxiliary nozzle 43 to the central side of the rotary table 2 and the section of 20 mm from the position of the peripheral edge of the wafer W to the outer peripheral side of the rotary table 2, is designated as Experimental Example 2-1. In addition, an example in which 52 gas discharge holes 44 were formed in a range d2 covering the section of 24 mm from the position of the inner peripheral edge of the wafer W close to the central side of the rotary table 2 in the central-side auxiliary nozzle 43 to the central side of the rotary table 2, is designated as Experimental Example 2-2. In addition, an example in which 24 gas discharge holes 44 were formed in a range d3 covering the section of 14 mm spaced apart at a distance 10 to 24 mm from the inner peripheral edge of the wafer W close to the central side of the rotary table 2 in the central-side auxiliary nozzle 43 to the central side of the rotary table 2, is designated as Experimental Example 2-3.

The DCS gas was supplied from the central-side auxiliary nozzle 43 at a flow rate of 20 sccm, a heating temperature of the wafer W was set to 400 degrees C., a process pressure was set to 100 Pa, and flow rates of the Ar gas, the H₂ gas and the NH₃ gas were set to 2,000 sccm, 600 sccm, and 300 sccm, respectively. The rotary table 2 was rotated at a rotational speed of 10 rpm and a cycle of the film-forming process shown in the embodiment was repeated 139 times to form a SiN film. The film thickness distribution of the SiN film formed on the wafer W was investigated in each of Experimental Examples 2-1 to 2-3.

FIG. 14 shows the results of the investigation. A position where a maximum value of the film thickness in Experimental Examples 2-1 to 2-3 was measured was a position closest to the central side of the rotary table 2 in Experimental Example 2-3. According to this result, it can be said that the film thickness can be made approximate to the film thickness distribution where the film thickness becomes thicker toward the central side of the rotary table 2, by forming the gas discharge holes 44 at the central side of the rotary table 2 rather than the position of the inner peripheral edge of the wafer W close to the central side of the rotary table 2. As shown in FIG. 14, an optimum range of the region in which the gas discharge holes 44 are formed was the range d3 covering the section of 14 mm spaced apart at a distance 10 to 24 mm from the inner peripheral edge of the wafer W close to an inner periphery of the rotary table 2 in the central-side auxiliary nozzle 43 to the central side of the rotary table 2. From this, the gas discharge holes 44 may be formed beyond a distance of 8 mm from the position of the peripheral edge of the wafer W to the outer peripheral side of the rotary table 2 in consideration of the margin.

In addition, by using the central-side auxiliary nozzle 43 shown in Experimental Example 2-3, the film thickness distribution of the film formed on the wafer W depending on the flow rates of the DCS gas and the N₂ gas discharged from the central-side auxiliary nozzle 43 was investigated. Except for the flow rate ratio (the flow rate of the DCS gas/the flow rate of the N₂ gas) of the DCS gas and the carrier gas (the N₂ gas) which was set to (20/0) sccm, (40/0) sccm, (20/200) sccm, and (20/400) sccm, examples set in the same manner as in Experimental Example 2-3 are designated as Experimental Examples 2-4, 2-5, 2-6, and 2-7, respectively.

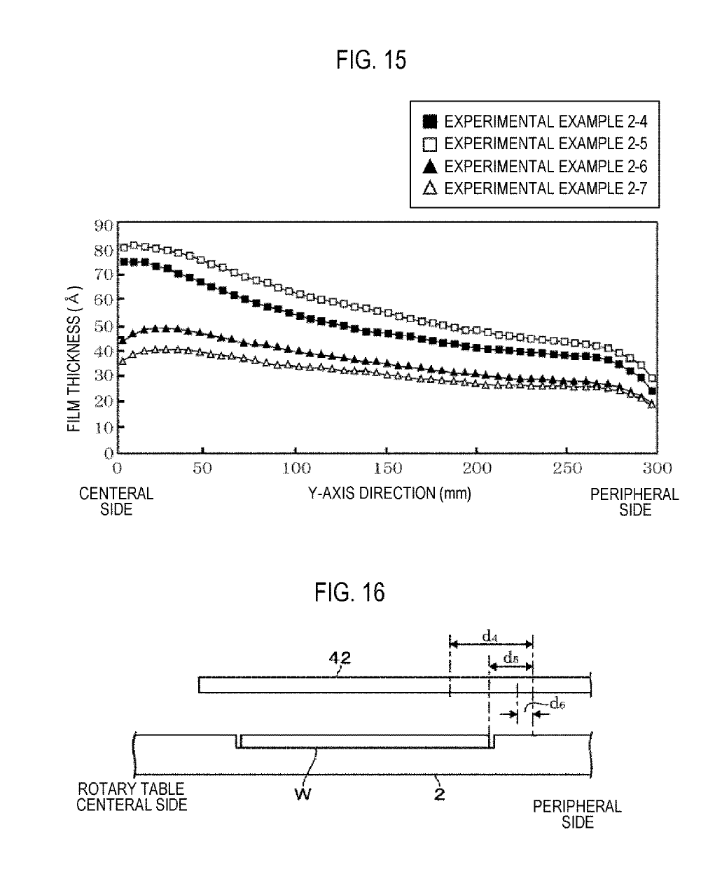

FIG. 15 shows these results. A position where a maximum value of the film thickness in Experimental Examples 2-4 to 2-7 is measured was a position of the peripheral edge closest to the central side of the rotary table 2 in the wafer W in Experimental Example 2-4. According to this result, it can be said that the film thickness can be made approximate to the film thickness distribution where the film thickness becomes thicker toward the central side of the rotary table 2, by decreasing the flow rate of the DCS gas and also reducing the flow rate of the carrier gas to increase the partial pressure of the DCS gas.

### [Verification Test 3]

The following test was conducted to investigate the film thickness distribution of the film formed on the wafer W depending on an optimum formation position of the gas discharge holes 44 in the peripheral-side auxiliary nozzle 42 and a flow rate of the discharged DCS gas. As shown in FIG. 16, an example in which 110 gas discharge holes 44 were formed in a range d4 covering the section of 60 mm which includes the section of 26 mm from a position of a peripheral edge of the wafer W close to the outer peripheral side of the rotary table 2 in the peripheral-side auxiliary nozzle 42 to the outer peripheral side of the rotary table 2, and the section of 34 mm from the position of the peripheral edge of the wafer W to the central side of the rotary table 2, is designated as Experimental Example 3-1. An example in which 60 gas discharge holes 44 were formed in a range d5 covering the section of 26 mm from the position of the peripheral edge of the wafer W close to the outer peripheral side of the rotary table 2 in the peripheral-side auxiliary nozzle 42 to the outer peripheral side of the rotary table 2, is designated as Experimental Example 3-2. An example in which 28 gas discharge holes 44 were formed in a range d6 covering the section of 15 mm spaced apart at a distance 11 to 26 mm from the position of the peripheral edge of the wafer W close to the outer peripheral side of the rotary table 2 in the peripheral-side auxiliary nozzle 42 to the outer peripheral side of the rotary table 2, is designated as Experimental Example 3-3.

The DCS gas was supplied from the peripheral-side auxiliary nozzle 42 at a flow rate of 20 sccm, a heating temperature of the wafer W was set to 400 degrees C., a process pressure was set to 100 Pa, and flow rates of the Ar gas, the H₂ gas, and the NH₃ gas were set to 2,000 sccm, 600 sccm, and 300 sccm, respectively. The rotary table 2 was rotated at a rotational speed of 10 rpm and a cycle of the film-forming process shown in the embodiment was repeated 139 times to form a SiN film. The film thickness distribution of the SiN film formed on the wafer W was investigated in each of Experimental Examples 3-1 to 3-3.

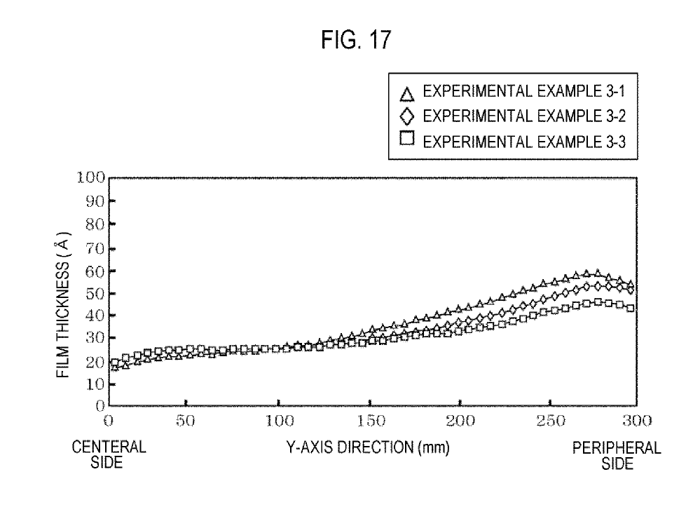

FIG. 17 shows the results of the investigation. A position where a maximum value of the film thickness in Experimental Examples 3-1 to 3-3 was measured was a position closest to the outer wall side of the vacuum vessel 1 in Experimental Example 3-3. According to this result, it can be said that the film thickness can be made approximate to the film thickness distribution where the film thickness becomes thicker toward the outer peripheral side of the rotary table 2, by allowing the gas discharge holes 44 formed in the peripheral-side auxiliary nozzle 42 to be positioned at the outer peripheral side of the rotary table 2 rather than the peripheral edge of the wafer W close to the outer peripheral side of the rotary table 2. As shown in FIG. 17, an optimum range of the region in which the gas discharge holes 44 are formed was the range d6 covering the section of 15 mm spaced apart at a distance 11 to 26 mm from the position of the peripheral edge of the wafer W close to the outer peripheral side of the rotary table 2 in the peripheral-side auxiliary nozzle 42 to the outer peripheral side of the rotary table 2. From this, the gas discharge holes 44 may be formed beyond a distance of 9 mm from the position of the peripheral edge of the wafer W to the outer peripheral side of the rotary table 2 in consideration of the margin.

In addition, by using the peripheral-side auxiliary nozzle 42 shown in Experimental Example 3-3, the film thickness distribution of the film formed on the wafer W depending on the flow rates of the DCS gas and the N₂ gas discharged from the peripheral-side auxiliary nozzle 42 was investigated. Except that the flow rate ratio (flow rate of the DCS gas/flow rate of the N₂ gas) of the DCS gas and the carrier gas (the N₂ gas) was set to (20/0) sccm, (40/0) sccm, (20/200) sccm, and (20/400) sccm, examples set in the same manner as in Experimental Example 3-3 are designated as Experimental Examples 3-4, 3-5, 3-6, and 3-7, respectively.

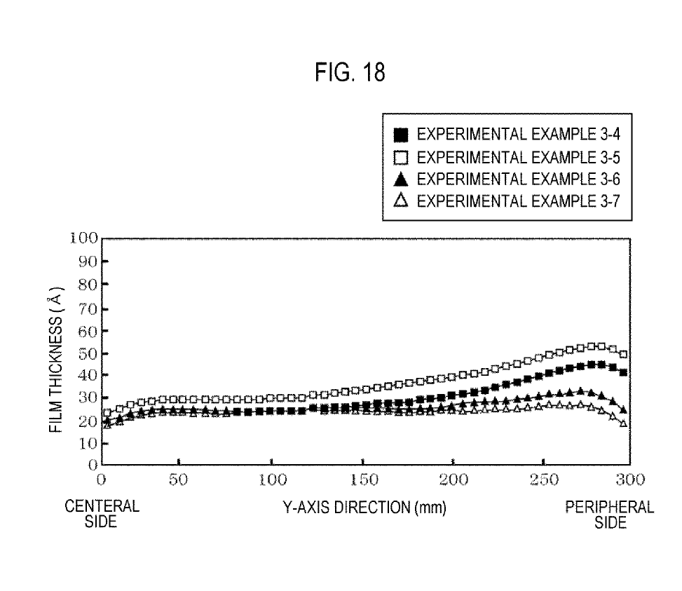

FIG. 18 shows these results. In Experimental Example 3-4, a position where a maximum value of the film thickness in Experimental Examples 3-4 to 3-7 was measured was a position closest to the outer peripheral side of the rotary table 2 in the peripheral edge of the wafer W. According to this result, it can be said that the film thickness can be made approximate to the film thickness distribution where the film thickness becomes thicker toward the peripheral edge close to the outer peripheral side of the rotary table 2 in the wafer W, by decreasing the flow rate of the DCS gas and also reducing the flow rate of the N₂ gas to increase the partial pressure of the DCS gas.

The present disclosure relates to a technique for supplying a source gas to a substrate mounted on a rotary table, using gas nozzles that extend in a direction intersecting with a movement path of the rotary table and include gas discharge holes formed to discharge gases downward. Defining a central side and a peripheral wall side of a vacuum vessel as an inner side and an outer side, in addition to a main nozzle for supplying the source gas to the entire passage region of the substrate when viewed in the inward and outward directions, auxiliary nozzles may be used to compensate for the shortage of the source gas supplied from the main nozzle. Further, the central-side auxiliary nozzle supplies the source gas to an inner region of the passage region of the substrate on the rotary table, and the peripheral-side auxiliary nozzle supplies the source gas to an outer region of the passage region of the substrate on the rotary table. Thus, it is possible to supply the activated gas to peripheral edges close to the inner and outer regions of the substrate where the activity of the source gas is low when being supplied from the main nozzle. This improves the in-plane uniformity of a film formed on the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film-forming apparatus for forming a thin film on a substrate by performing, inside a vacuum vessel, a cycle of sequentially supplying a source gas and a reactant gas reacting with the source gas to generate a reaction product a plurality of times, the film-forming apparatus comprising:
a rotary table installed inside the vacuum vessel, and including a substrate mounting region, on which the substrate is mounted, formed at one surface side of the rotary table, the rotary table being configured to rotate the substrate mounting region;
a heating part configured to heat the substrate mounted on the rotary table;
a first process region in which the source gas is supplied toward the substrate mounting region of the rotary table to perform a first process;
a second process region defined apart from the first process region in a circumferential direction of the rotary table via a separation portion, and in which the reactant gas is supplied to perform a second process; and
a main nozzle, a central-side auxiliary nozzle and a peripheral-side auxiliary nozzle installed in the first process region to extend in a direction intersecting with a movement path of the rotary table and along a rotational direction of the rotary table, each of the main nozzle, the central-side auxiliary nozzle and the peripheral-side auxiliary nozzle including gas discharge holes formed to discharge the source gas downward in a longitudinal direction thereof, wherein
when a central side and a peripheral wall side of the vacuum vessel are respectively defined as an inner side and an outer side, respectively,
the gas discharge holes of the main nozzle are formed to face an entire region of a passage region of the substrate when viewed in inward and outward directions and to face inner and outer regions of the passage region of the substrate on the rotary table,
the gas discharge holes of the central-side auxiliary nozzle are formed in a region facing the inner region of the passage region of the substrate on the rotary table,
the gas discharge holes of the peripheral-side auxiliary nozzle are installed in a region facing the outer region of the passage region of the substrate on the rotary table, and
each of the central-side auxiliary nozzle and the peripheral-side auxiliary nozzle is installed to compensate for a shortage of the source gas supplied to an inner peripheral portion and an outer peripheral portion of the substrate from the main nozzle.

2. The film-forming apparatus of claim 1, wherein a flow velocity of a process gas supplied from each of the central-side auxiliary nozzle and the peripheral-side auxiliary nozzle is 40 sccm or less.

3. The film-forming apparatus of claim 1, further comprising:
a flow rate adjuster configured to change a flow rate ratio of a process gas to a flow rate of a carrier gas in each gas discharged from the central-side auxiliary nozzle and the peripheral-side auxiliary nozzle.

4. The film-forming apparatus of claim 1, wherein the gas discharge holes of the central-side auxiliary nozzle are formed in a region spaced apart by a distance of 8 to 26 mm from an outer edge of the passage region of the substrate in a direction orienting an outer edge of the rotary table in a plan view.

5. The film-forming apparatus of claim 1, wherein the gas discharge holes of the peripheral-side auxiliary nozzle are formed in a region spaced apart by a distance of 9 to 28 mm from an inner edge of the passage region of the substrate in a direction orienting an inner edge of the rotary table in a plan view.

6. The film-forming apparatus of claim 1, wherein the peripheral-side auxiliary nozzle includes a flow passage through which the source gas travels along the rotational direction of the rotary table so that a temperature of the source gas is increased by heat radiated from the rotary table.

7. A film-forming method for forming a thin film on a substrate by performing, inside a vacuum vessel, a cycle of sequentially supplying a source gas and a reactant gas reacting with the source gas to generate a reaction product a plurality of times, the film-forming method comprising:
mounting the substrate on one surface side of a rotary table installed inside the vacuum vessel;
heating the substrate; and
repeatedly performing an operation of supplying and adsorbing the source gas to and onto the substrate by using gas nozzles, which are installed in a first process region and have gas discharge holes formed to discharge the source gas downward in a longitudinal direction, while rotating the substrate on the rotary table, and an operation of supplying, a plurality of times, the reactant gas to the substrate in a second process region separated from the first process region by a separation portion, wherein
when a central side and a peripheral wall side of the vacuum vessel are respectively defined as an inner side and an outer side, respectively,
in the first process region, an operation of supplying, by a main nozzle, the source gas to an entire region of a passage region of the substrate when viewed in inward and outward directions and each of an inner region and an outer region of the passage region of the substrate on the rotary table, an operation of supplying, by a central-side auxiliary nozzle, the source gas to an inner region of the passage region of the substrate on the rotary table, and an operation of supplying, by a peripheral-side auxiliary nozzle, the source gas to an outer region of the passage region of the substrate on the rotary table are performed.

8. A non-transitory computer-readable storage medium storing a computer program that is used in a film-forming apparatus for forming a thin film on a substrate, by performing, inside a vacuum vessel, a cycle of sequentially supplying a source gas and a reactant gas reacting with the source gas to generate a reaction product a plurality of times, wherein the computer program incorporates a group of steps so as to execute the film-forming method according to claim 7.
